(19) United States
(12) Patent Application Publication
(10) Pub. No.: US 2007/0170564 A1
(43) Pub. Date: Jul. 26, 2007

(54) CHIP CARD MODULE

(75) Inventors: BERNHARD DRUMMER, Tegernheim (DE); FRANK PUESCHNER, Kelheim (DE); WOLFGANG SCHINDLER, Regenstauf (DE)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Munich (DE)

(21) Appl. No.: 11/614,847

(22) Filed: Dec. 21, 2006

(30) Foreign Application Priority Data
Dec. 21, 2005 (DE) 10 2005 061 345.4
Apr. 28, 2006 (DE) 10 2006 019 925.1

(51) Int. Cl. H01L 23/02

(52) U.S. Cl. 257/678

(57) ABSTRACT

A smart card module including a substrate having an upper face and a lower face, contact arrays arranged on the substrate lower face, conductor structures, which have vias arranged in cutouts in the substrate, arranged on the substrate upper face and connected to the contact arrays, a chip having connecting contacts which are electrically conductively connected to the conductor structures, wherein the chip is mounted by a mount on the substrate upper face or on the conductor structures, and an encapsulation, which covers the chip and at least a part of the conductor structures and of the substrate upper face.

### CROSS-REFERENCE TO RELATED APPLICATION

This application claims priority to German Patent Application Serial No. 102005061345.4, which was filed Dec. 21, 2005, and is incorporated herein by reference in its entirety.

### BACKGROUND

The invention relates to a smart card module having contact arrays which are applied to a substrate and having an encapsulated chip, whose connecting contacts are coupled to the contact arrays.

Smart cards have a broad field of use, for example for data storage, as access control or for payment purposes.

Data can be transferred between the smart card and a reader by means of contacts, by contacts of the reader touching contact arrays which are accessible on an upper face of the smart card. Alternatively, the data can be transferred without contacts, by means of an electromagnetic field. The contact card normally has a coil for this purpose. Cards also exist which have not only a contact-based interface but also an interface without contacts. Smart cards such as these are also referred to as dual-interface cards.

In order to produce a smart card, a smart card module can be inserted into a cavity in a smart card body and can be connected to it, for example by adhesive bonding.

The smart card module normally has contact arrays which are arranged on a substrate and whose front faces are still accessible after fitting of the smart card module, and a chip which is mounted on an opposite face of the substrate to the contact arrays. Recesses, also referred to as bonding holes, can be provided in the substrate, so that connecting contacts on the chip can make contact via bonding wires with rear faces of the contact arrays in the recesses.

Conductor structures can also be applied to smart card modules for dual-interface cards, on the opposite face of the substrate to the contact arrays, in order to make contact with a coil, which is normally arranged in the card interior, and to connect this via the conductor structures and bonding wires to the connecting contacts of the chip.

The chip and the bonding wires are normally encapsulated in order to protect the chip and, in particular, the sensitive bonding wires. In this case, the adhesion of the encapsulation material on the substrate is normally better in the bonding holes on the rear faces of the contact arrays.

The design results in delaminations occurring, in particular in the bonding holes, between the encapsulation material and the rear face of the contact arrays. The delaminations are caused by mechanical and/or thermal stress, which acts on the smart card module during the further processing or subsequently during daily use. This is caused by weak adhesion of a large number of encapsulation materials. Another reason may be the physical construction of the substrate. The delaminations can lead to bonding wires being torn off, and to electrical failures.

The following effect can occur when using encapsulation materials which adhere firmly on the substrate. Since the bonding wires are firmly anchored in the encapsulation but are connected to the contact arrays in the bonding holes, three-dimensional relative movement between the substrate and the contact arrays, for example as a result of thermal or mechanical loading, can lead to delaminations of the encapsulation material in the bonding holes and to the bonding wires which are anchored in the encapsulation material being torn off. These relative movements occur, for example, in the case of contact arrays which are adhesively bonded to the substrate. The delaminations are caused by the reduced adhesion of the encapsulation material on the rear face of the contact arrays and on the conductor structures. These occur in particular in contact array embodiments which comprise gold.

### DESCRIPTION OF THE DRAWINGS

FIG. 1 shows one embodiment of a smart card module with which contact is made using a wire-bonding technique.

FIG. 2 shows one embodiment of a smart card module with which contact is made using flip-chip technology.

FIGS. 3A to 3C show the contacts for further exemplary embodiments of a smart card module.

FIG. 4 shows a plan view of the layout of one exemplary embodiment of a smart card module.

### DESCRIPTION OF THE INVENTION

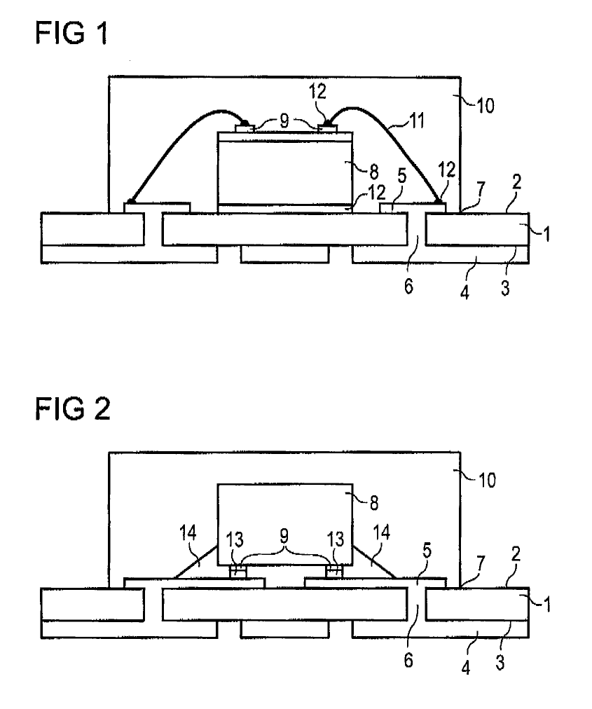

FIG. 1 shows one exemplary embodiment of a smart card module having a substrate 1 with an upper face 2 and a lower face 3. One exemplary embodiment of the substrate 1 is formed from glass-fiber-reinforced epoxy resin. The substrate 1 is metallized both on the upper face 2 and on the lower face 3. The structured metallization on the lower face 3 of the substrate 1 forms contact arrays 4. Exemplary embodiments of contact arrays and/or the conductor structures are composed of gold, whose electrical conductivity is particularly good.

In one exemplary embodiment, the contact arrays 4 are designed in such a manner that at least their dimensions comply with the requirements of the ISO Standard. If the dimensions of the contact arrays comply with the ISO Standard, the exemplary embodiment of the smart card module can be used in standardized smart cards.

In one exemplary embodiment, the design of the contact arrays and/or of the conductor structures has a structured copper sheet which can be fitted to the substrate in a simple manner.

By way of example, the contact arrays 4 are laminated onto the substrate as a copper sheet that is coated with adhesive on one side. The adhesive is applied as a film either to the copper sheet and/or to the substrate. The copper sheet typically has a thickness in the range from 30 to 40 μm, in particular in the region of approximately 35 μm. The sheet is then photolithographically structured and a layer composed of nickel and/or gold is electroplated onto it.

The lamination of the contact arrays and conductor structures by means of an adhesive is dependent on the substrate having a rough surface on which the encapsulation material can adhere well.

In a further exemplary embodiment, the contact arrays and conductor structures are laminated without adhesive, which results in low-cost production. The metallization which forms the conductor structures 5 on the upper face 2 of the substrate 1 can be applied to the substrate 1 without adhesive.

Exemplary embodiments can also be produced with combinations of application without adhesive and application by means of an adhesive.

In the exemplary embodiment in FIG. 1, the conductor structures 5 on the upper face 2 of the substrate 1 and the contact arrays 4 are conductively connected to one another via so-called vias 6, through cutouts in the substrate 1. The vias 6 are inserted into cutouts in the substrate 2.

Furthermore, the exemplary embodiment of the smart card module covers a chip 8 which is applied to the upper face 2 of the substrate 1 by means of an adhesive 12. Connecting contacts 9, which are arranged on a side of the chip 8 facing away from the substrate 1, are connected to the conductor structures 5 via bonding wires 11 using a wire-bonding method. In one exemplary embodiment, the bonding wires are in the form of gold wires. The use of the wire-bonding process for connection of the chip 8 to the conductor structures allows the use of conventional contact-making technologies.

The bonding wire contact is therefore not made in a bonding hole, that is to say on a rear face of the contact arrays 4, but on the conductor structures 5 which are applied to the upper face 2 of the substrate 1.

In order to protect the chip 8 and the bonding wires 11, the chip 8 and the bonding wires 11 are encapsulated by an encapsulation material. One possible encapsulation method is so-called “molding”, in which a molding compound, covering the chip 8, is applied to the substrate upper face 2, so that it covers the chip 8 and the bonding wires 11. The molding compound cures after it has been applied. By way of example, the molding compound is composed of epoxy resins and is in the form of a thermosetting plastic.

In order to ensure that the area extent of the conductor structures 5 which are touched by the encapsulation material is small in comparison to the extent of the area on the plane of the substrate upper face 2 that is covered by the encapsulation, the diameter of the vias 6 is small, in particular as small as possible. In one exemplary embodiment, the diameter of the vias is less than or equal to 0.8 mm, and in a further embodiment it is less than or equal to 0.5 mm. Further improvements can be achieved if the diameter is less than or equal to 0.4 mm, or even less than or equal to 0.3 mm. The small diameter of the vias also results in the conductor structures which surround the vias having a small area.

In order to improve the capability of this arrangement to resist thermomechanical loading, the wire lengths of the bonding wires 11 in one exemplary embodiment are shorter than 2.5 mm, in particular shorter than 2 mm. Relatively short wire lengths also reduce the distance between the bonding wires and the outer areas of the encapsulation 10. This is advantageous since the maximum amount of force is exerted in the outer areas when loads are applied to the smart card and the contact arrays. In consequence, in particular the rim 7 of the encapsulation 10, which touches the substrate, is endangered in that the encapsulation 10 is detached in this area, which can result in functional failures as a result of torn wires resulting from this.

In one exemplary embodiment, the encapsulation 10 has a flat extent so that the vias are located in the area which is covered by the encapsulation, and/or in the area which is surrounded by the rim 7. This protects the vias 6 against environmental influences, for example moisture and gases.

Exemplary embodiments of a smart card module which is particularly mechanically resistant to fracture are produced by the encapsulation being provided using so-called transfer-molding technology.

The wire contact with the conductor structures 5 means that it is impossible for any delamination of the encapsulation compound to occur in the bonding hole, thus leading to bonding wires which are anchored in the encapsulation material being torn off, for example as a result of the relative movement between the upper face 2 and the contact arrays 4 which have been adhesively bonded on. Furthermore, the required area extent of the conductor structures with the vias for making contact with the bonding wire is reduced, since the size of the bonding holes must be at least sufficient to allow the contact to be made in the bonding hole.

In the refinement described above, the vias 6 cannot be seen from the lower face of the smart card module. These are so-called “blind vias”.

In one exemplary embodiment, the contact arrays are designed in such a manner that the metallization is laminated onto the lower face 3 of the substrate 1, without adhesive, in order to form the contact arrays 4. The vias 6 can normally be seen in this embodiment, and they are also referred to as “visible vias”. This refinement is less costly.

In one exemplary embodiment, contact is made with the bonding wire by means of a so-called wedge-on bump contact, referred to for short as WOB. This contact has very good adhesion and is therefore particularly suitable for making contact with a bonding wire which is in the form of a gold wire on the conductor structure 5.

The application of the chip 8 directly to the substrate 1 results in a thick buffer zone between the lower face of the substrate with the contact arrays 4 and the chip 8, which absorbs possible mechanical loads which act on the contact arrays 4. Alternative refinements which have a chip holder are also possible.

FIG. 2 shows a further exemplary embodiment of the smart card module, in which the chip 8 is applied to the upper face 2 of the substrate 1, and makes contact with the conductor structures 5, using flip-chip technology. The contact between the chip and the conductor structures using flip-chip technology allows flatter embodiments of the smart card module.

In the case of flip-chip contact, the connecting contacts 9 on the chip 8 are arranged on the side of the chip 8 which faces the upper face 2 of the substrate 1. The connecting contacts 9 on the chip 8 are connected to the conductor structures 5 via contact-making elements 13. The contact is made by application of a force, which acts on the chip 8 in the direction of the substrate 2, during chip assembly. In order to fix the chip 8, it is connected by means of adhesive or so-called underfiller 14 to the substrate 1, or to the conductor structures 5.

The difference between the line structures 5 in this exemplary embodiment and those in the exemplary embodiment illustrated in FIG. 1 is that the geometry of the conductor structures 5 is configured in such a manner that they are arranged under the connecting contacts 9 of the installed chip.

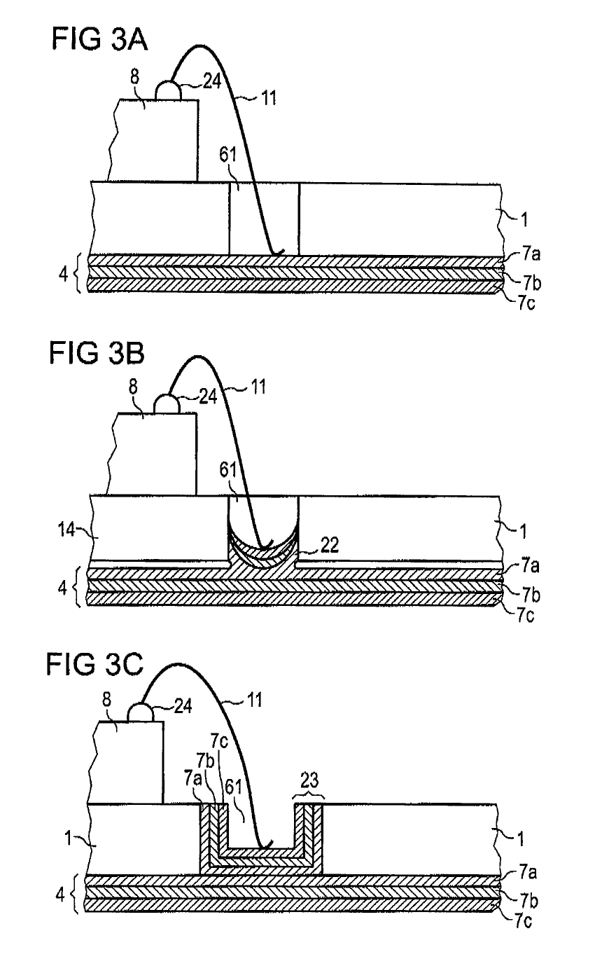

FIG. 3A shows a detail of a further exemplary embodiment of a chip module. The illustrated detail shows one exemplary embodiment of wire-bonding contact for the chip 8.

At least one via 61 is provided in the substrate 1. A bonding wire 11 is passed through the via 61 from the chip connection, and is electrically conductively connected to the metallization 4 which covers one side of the via 61.

The opening of the via 61 is advantageously less than or equal to 0.8 mm, and in one particularly advantageous refinement is less than or equal to 0.5 mm. Further improvements are achieved by the opening width being chosen to be less than or equal to 0.4 mm or less than or equal to 0.3 mm, with an opening width of 0.4 mm having been found to be particularly suitable.

The bonding connection is made, for example, by starting with the bonding appliance on the chip 8. In this case, a so-called “nail head” 24 is placed on the chip connection, for which purpose the start of the bonding wire is fused on. The bonding wire is then passed from this “nail head” into the via 61, which is formed in the substrate 1, and the second end of the bonding wire is attached to the rear face of the contact array 4 by means of a so-called “wedge contact”. The contact-making sequence may be reversed.

In the exemplary embodiment illustrated in FIG. 3A, the illustrated connecting contact of the chip is arranged sufficiently close to the edge of the chip 8 to allow a wire bonding connection 11 to be placed on the connecting content directly from the rear face of the contact array 4, within the via 61. The wire bonding connection 11 ends with a “wedge contact” on the bottom of the via 61, in which case it may be advantageous to also apply a nickel layer 7b and a gold layer 7c on the laminated copper layer 7a of the contact array 4 within the via 61.

FIG. 3B shows how the contact is made in a further exemplary embodiment. FIG. 3B illustrates an adhesive layer 14 which holds the lamination together between the copper layer 7a and the substrate 1. A fillet bead, from which adhesive emerges into the via 61 through the lamination, is formed at the interface between the copper layer 7a and the via 61. This emerging adhesive is covered by a copper layer 22 in the refinement shown in FIG. 6B. This copper layer which covers the emerging adhesive has a reinforcing effect for the retention of the contact arrays 4 on the substrate 1. As can be seen in FIG. 3B, a nickel layer 7b and a gold layer 7c are also additionally applied to the copper layer 7a.

FIG. 3C shows how contact is made in a further exemplary embodiment. In the refinement shown in FIG. 3C, the internal area which is formed by the via 61 and the copper layer 7a of the contact array 4 is completely metallized. In this case, in the illustrated exemplary embodiment, the same layer sequence 23 of the contact array 4 is applied. This means that a copper layer 7a is applied first of all, followed by a nickel layer 7b and finally a gold layer 7c. The copper layer 7a is arranged at the bottom, on the copper layer 7a of the contact array 4.

The “wedge contact” of the bonding connection 11 is placed on the gold layer 7c within the via 61. The metallization of the via 61 as shown in FIG. 3C, or at least the coverage of the fillet bead as shown in FIG. 3B, has the advantage that this prevents molding compound from entering the fillet bead during a subsequent molding process, and the lamination of the contact area 4 with the contact surface 3 being damaged.

Although FIGS. 3A and 3C do not show the adhesive 14 that holds the lamination together, it is self-evident that an adhesive such as this can also be used in both refinements.

In the exemplary embodiments illustrated in FIGS. 3A to 3C, the metallization 4 is in the form of three layers. The sequence is produced by first of all forming a copper layer (Cu layer) 7a directly on the substrate 1, with a nickel layer (Ni layer) 7b then being electrochemically formed on it, onto which, in turn, a gold layer (Au layer) 7c is formed, likewise electrochemically.

The nickel layer 7b and the gold layer 7c are applied electrochemically and, in the exemplary embodiments in FIGS. 3B and 3C, are likewise applied to the inner wall of the via 61 on the copper layer 7a. The “wedge contact” for the wire bonding connection 11 in the via 61 is in this case placed on the gold layer 7c in the bottom of the via 61.

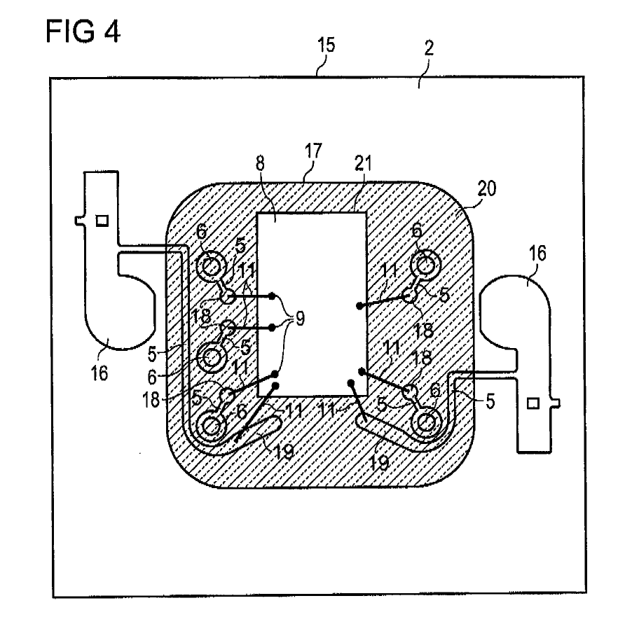

FIG. 4 shows a plan view of one exemplary embodiment of a smart card module with an outer rim 15 in which the chip 8 is mounted using a wire-bonding technique. Conductor structures 5 are applied to the upper face 2 of the substrate.

The conductor structures 5 are designed such that they are connected to vias 6 and have a connecting area 18. The bonding wire 11 is mounted in this connecting area 18, and is connected to the connecting contacts 9 on the chip 8.

Furthermore, the exemplary embodiment of the smart card module has conductor structures which are in the form of coil connecting contacts 16 for making contact with a coil. These conductor structures also have connecting areas 19 which are connected via bonding wires 11 to the connecting contacts 9 on the chip 8.

The area extent of the conductor structures 5 on the substrate 1 which is covered by the encapsulation material is small in comparison to the area which is covered by the encapsulation 10. In order to illustrate the physical extent of the encapsulation 10, an encapsulation contour 17 of the encapsulation rim 7, which touches the substrate surface or the conductor structures 5, is projected onto the upper face 2 of the substrate. The conductor structures which are applied to the upper face 2 of the substrate 1 occupy only a small proportion of the area within the encapsulation contour 17.

The illustration likewise shows a chip contour 21 of that area of the upper face 2 on which the chip 8 is mounted. The chip contour is the projection of the rim of a means which touches the substrate surface 2 or the conductor structures 5, for mounting of the chip 8. By way of example, this may be the adhesive 12 or the underfiller 14. If the adhesive 12 ends flush with the chip lower face, the chip contour 21 corresponds to the chip geometry as described in this exemplary embodiment.

In order to encapsulate the chip 8 and its connections 9, the encapsulation material touches the chip 8, the bonding wires 11 and an area 20 on the substrate upper face 2 with conductor structures 5 between the encapsulation contour 17 and the chip contour 21, in particular such that the connecting areas 18, 19 as well as the vias 6 are covered.

No conductor structures 5 are arranged on the majority of the shaded area 20, in which the encapsulation material touches the substrate upper face 1 or the conductor structures 5. The adhesion of the encapsulation material on the chip 8 is normally better than on the conductor structures 5. This ensures very good adhesion of the encapsulation material on the substrate 2 as well as on the chip surface. The smaller the relatively flat extent of the conductor structures 5 is within the area that is surrounded by the encapsulation contour 17, the better is the adhesion of the encapsulation 10.

Reliable adhesion of the encapsulation, which considerably reduces the risk of delaminations and wires being torn off, is ensured if the area extent of the conductor structures 5 on the upper face 2 between the encapsulation contour 17 and the chip contour 21 occupies no more than one fifth of the area which is surrounded by the encapsulation contour 17.

It should be noted that the conductor structures 5 surround not only the metallized areas on the substrate surface 2 as well as the cutouts, in particular vias 6, but also any bonding holes which may be present. The adhesion is improved if conductor structures occupy only a maximum of 15% of the area extent of the area which is surrounded by the encapsulation contour 17. Further improvements are obtained by the conductor structures occupying only a maximum of 10% of the area extent of the area which is surrounded by the encapsulation contour 17. Furthermore, improvement is also possible if the conductor structures comprise only a maximum of 5% of the area extent.

Such optimization of the area extent of the conductor structures can be achieved by a further reduction in the diameters of the vias and of the area extent of the conductor structures, in particular of those which are used as a supply to the coil contact areas 16.

It should be noted that, in the case of wire-bonding contact, the conductor structures 5 are arranged essentially in the area between the encapsulation contour 17 and the chip contour 21. Normally, no conductor structures are provided within the chip contour 21.

In contrast to this, in the case of flip-chip contact, a part of the conductor structures 5 is also provided within the chip contour 21 in order to make contact with the connecting contacts 5 on that side of the chip 5 which faces the substrate 1. However, these do not influence the adhesion of the encapsulation material on the substrate 1 or on the conductor structures, since this area is covered by the chip 8.

It should be noted that the features of the exemplary embodiments illustrated in the figures can be combined with one another.

One exemplary embodiment of the smart card module according to the invention has a substrate with a substrate upper face and a substrate lower face as well as contact arrays which are arranged on the substrate lower face. Furthermore, conductor structures are provided, are arranged on the substrate upper face and have vias which, arranged in cutouts in the substrate, are connected to the contact arrays. The smart card module also has a chip with connecting contacts which are connected to the conductor structures, with the chip being mounted by a means for mounting of the chip on the substrate upper face or on the conductor structures, and encapsulation for encapsulation of the chip, which encapsulation is applied to the chip, at least a part of the conductor structures and the substrate upper face. A smart card module such as this is robust with respect to mechanical and thermal stress.

The adhesion of the encapsulation material is normally better on the substrate than on metal. The vias result in the area extent of the conductor structures being small, so that the encapsulation adheres well on the substrate. This results in an increase in the life of the smart card module, and in reduced array failure rates.

In one exemplary embodiment, the encapsulation has a rim which touches the substrate upper face or the conductor structures and is applied in such a manner that, in an area between an encapsulation contour of the rim and the substrate upper face and a chip contour of a rim of the means on the substrate upper face, the area extent of the conductor structures on the substrate upper face occupies a maximum of one fifth of the area extent of an area which is surrounded by the encapsulation contour. The good adhesion characteristics of the substrate are clearly predominant with this ratio.

In order to simplify production, in particular in order to allow the machines that are used for encapsulation to be cleaned easily, the adhesion of the encapsulation on the surface of the substrate is greater than on the metallic conductor structures.

One exemplary embodiment of the smart card module has further contact pads on the upper face of the substrate, which are designed to make contact with a coil, in order to allow the smart card module to be used in a dual-interface card.

What is claimed is:

1. A smart card module, comprising:
a substrate having an upper face and a lower face;
contact arrays arranged on the substrate lower face;
conductor structures, which have vias arranged in cutouts in the substrate, arranged on the substrate upper face and connected to the contact arrays;
a chip having connecting contacts which are electrically conductively connected to the conductor structures, wherein the chip is mounted on the substrate upper face or on the conductor structures; and
an encapsulation, which covers the chip and at least a part of the conductor structures and of the substrate upper face.

2. The smart card module as claimed in claim 1, wherein at least one via is formed in the substrate and at least one wire bonding connection is provided on the contact array within the at least one via and is passed to a further connecting contact on the chip.

3. The smart card module as claimed in claim 2, wherein the via has an open width of ≦0.8 mm.

4. The smart card module as claimed in claim 1, wherein the encapsulation has a rim which touches the substrate upper face or the conductor structures, and the encapsulation is positioned such that the area extent of the conductor structures on the substrate upper face between the encapsulation rim contour and the chip contour occupies a maximum of one fifth of the area which is surrounded by the encapsulation rimcontour.

5. The smart card module as claimed in claim 4, wherein the area extent of the conductor structures on the substrate upper face occupies a maximum of one fifth of the area extent of the area which is surrounded by the encapsulation rim contour.

6. The smart card module as claimed in claim 1, wherein the dimensions of the contact arrays comply with the ISO Standard.

7. The smart card module as claimed in claim 1, wherein the contact arrays and/or the conductor structures touch the substrate.

8. The smart card module as claimed in claim 1, wherein an adhesive layer is provided between the contact arrays and the substrate, and/or between the conductor structures and the substrate.

9. The smart card module as claimed in claim 1, wherein all of the vias are arranged within the area which is surrounded by the encapsulation contour.

10. The smart card module as claimed in claim 1, wherein the adhesion of the encapsulation on the surface of the substrate is greater than on the conductor structures.

11. A smart card module, comprising:
a substrate having an upper face and a lower face;
contact arrays arranged on the substrate lower face;
conductive structures, which have vias arranged cutouts in the substrate, arranged on the substrate upper face and connected to the contact arrays;
a chip having connecting contacts which are electrically conductively connected to the conductor structures, wherein the chip is mounted via a chip mount on the substrate upper face or on the conductor structures; and
an encapsulation, which is applied to the chip, and to at least a part of the conductor structures and of the substrate upper face, wherein the encapsulation has a rim which touches the substrate upper face or the conductor structures, and the encapsulation is applied such that the area extent of the conductor structures on the substrate upper face between the encapsulation rim contour and the chip mount contour occupies a maximum of one fifth of the area extent which is surrounded by the encapsulation rim contour.

12. The smart card module as claimed in claim 11, wherein the area extent of the conductor structures on the substrate upper face occupies a maximum of one fifth of the area extent which is surrounded by the rim of the encapsulation.

13. The smart card module as claimed in claim 11, wherein at least one via is formed in the substrate and at least one wire-bonding connection is provided on the contact array within the at least one via and is passed to a further connecting contact on the chip, with the via having an opening width of ≦0.8 mm.

14. The smart card module as claimed in claim 13, in whichwherein touching surfaces of the via with a contact array form a fillet bead which is at least partially covered by at least one copper layer.

15. The smart card module as claimed in claim 13, in whichwherein the via and the contact array which covers this via form an area with walls which are completely metallized.

16. The smart card module as claimed in claim 11, wherein the connecting contacts of the chip are connected to the conductor structures via bonding wires using a wire bonding technique.

17. The smart card module as claimed in claim 11, wherein the connecting contacts of the chip are connected to the conductor structures using flip-chip technology.

18. The smart card module as claimed in claim 11, wherein the dimensions of the contact arrays comply with the ISO Standard.

19. The smart card module as claimed in claim 11, wherein the contact arrays and/or the conductor structures are laminated without adhesive.

20. The smart card module as claimed in claim 11, wherein the contact arrays and/or the conductor structures are applied by means of an adhesive.

21. The smart card module as claimed in claim 11, wherein the contact arrays and/or the conductor structures are composed of a structured copper sheet.

22. The smart card module as claimed in claim 11, wherein the contact arrays and/or the conductor structures are composed of gold.

23. The smart card module as claimed in claim 11, wherein the contact arrays and/or the conductor structures are composed of layers of copper, nickel and gold.

24. The smart card module as claimed in claim 11, wherein the diameter of one of the vias is less than or equal to 0.8 mm.

25. The smart card module as claimed in claim 11, wherein the contact arrays cover upper faces of the vias, and/or the conductor structures cover lower faces of the vias.

26. The smart card module as claimed in claim 11, wherein all of the vias are arranged within the area which is surrounded by the rim of the encapsulation.

27. The smart card module as claimed in claim 11, wherein the adhesion of the encapsulation on the surface of the substrate is greater than on the conductor structures.

28. The smart card module as claimed in claim 11, wherein the contact arrays and/or the conductor structures are composed of coil connecting contacts are arranged on the upper face of the substrate and are designed to make contact with a coil.

29. The smart card module as claimed in claim 11, wherein the chip 8 is connected to the substrate or to the conductor structures by an underfiller.

30. A smart card module, comprising:
a substrate having an upper face and a lower face;
contact arrays arranged on the substrate lower face;
conductor structures, which have vias arranged in cutouts in the substrate, are arranged on the substrate upper face and are connected to the contact arrays;
a chip having connecting contacts which are electrically conductively connected to the conductor structures;
a chip mounting means for mounting the chip on the substrate upper face or on the conductor structures; and
an encapsulation, which covers the chip and at least a part of the conductor structures and of the substrate upper face.
